(19) United States
(12) Patent Application Publication
(10) Pub. No.: US 2012/0118352 A1
(43) Pub. Date: May 17, 2012

(54) PHOTOELECTRIC CONVERSION MODULE AND PHOTOELECTRIC CONVERSION DEVICE

(75) Inventor: Yoshinobu Asami, Isehara (JP)

(73) Assignee: SEMICONDUCTOR ENERGY LABORATORY CO., LTD., Atsugi-shi (JP)

(21) Appl. No.: 13/293,180

(22) Filed: Nov. 10, 2011

(30) Foreign Application Priority Data
Nov. 12, 2010 (JP) 2010-254155

(51) Int. Cl. H01L 31/052

(52) U.S. Cl. 136/246

(57) ABSTRACT

A reflection member is provided for a space between photoelectric conversion cells or a periphery of the photoelectric conversion cells, which is the place not provided with the photoelectric conversion cell, so that a peak portion of the reflection member is higher than a surface of the photoelectric conversion cells. Accordingly; light having entered the space between the photoelectric conversion cells or the periphery of the photoelectric conversion cells, which does not contribute to power generation under normal circumstances, can be guided to the photoelectric conversion cell through reflection by the reflection member. Note that since the peak portion of the reflection member is higher than the surface of the photoelectric conversion cells, sunlight can be guided to the photoelectric conversion cell through one-time reflection, whereby the object can be achieved.

### BACKGROUND OF THE INVENTION

1. Field of the Invention

The present invention relates to a photoelectric conversion module and a photoelectric conversion device.

2. Description of the Related Art

In recent years, solar cells which generate electric power without carbon dioxide emissions have attracted attention from the point of view of global warming prevention. Since the Japanese government has started subsidies for solar cells and moreover solar cells have come to be less expensive recently, solar cells have been in widespread use not only in large-scaled solar power generation facilities but also in standard houses, e.g., on roofs of or outside the houses for power generation.

Therefore, a variety of methods have been suggested in order to increase the amount of electric power to be generated by solar cells. As one of those methods, a method is considered in which light having entered a region not provided with a photoelectric conversion cell is guided to the photoelectric conversion cell, so that the amount of electric power to be generated by a solar cell is increased.

As for the above method, for example, Patent Document 1 has suggested a method in which a light reflection portion is provided for a space between photoelectric conversion cells and a light-transmitting substrate is provided so as to cover the photoelectric conversion cells. According to this method, light having entered the space between the photoelectric conversion cells for which the photoelectric conversion cell is not provided is reflected first by the light reflection portion and then reflected further by the light-transmitting substrate, so that the light is guided to the photoelectric conversion cell.

### REFERENCE

[Patent Document 1] Japanese Published Patent Application No. H11-298029

### SUMMARY OF THE INVENTION

However, in the method as disclosed in Patent Document 1 in which the light having entered the space between the photoelectric conversion cells is guided to the photoelectric conversion cell by two-time reflections, most part of the light reflected by the light reflection portion goes outside because the second reflection is performed through total reflection at an interface of the light-transmitting substrate (i.e., the reflection is not performed at the light-transmitting substrate). Therefore, the proportion where the light having entered the space between the photoelectric conversion cells contributes to power generation is very small.

The present invention has been made in view of the foregoing technical background. Therefore, it is an object of the present invention to provide a photoelectric conversion module which generates a large amount of electric power and by which light having entered a region not provided with a photoelectric conversion cell can be converted into electricity with high efficiency.

In order to achieve the above object, the present inventor has focused on where to provide a reflection member for guiding incident light to a photoelectric conversion cell. Specifically, a reflection member may be provided for a space between photoelectric conversion cells or a periphery of a photoelectric conversion cell, which is a region not provided with the photoelectric conversion cell, so that a peak portion of the reflection member is placed on an incident light side as compared with a surface of the photoelectric conversion cell, that is the peak portion is higher than a surface of the photoelectric conversion cell. Thus, light having entered the space between the photoelectric conversion cells or the periphery of the photoelectric conversion cell, which does not contribute to power generation under normal circumstances, can be reflected by the reflection member to be guided to the photoelectric conversion cell. Further, since the peak portion of the reflection member is on the incident light side as compared with the surface of the photoelectric conversion cell, that is the peak portion is higher than a surface of the photoelectric conversion cell, sunlight can be guided to the photoelectric conversion cell by one-time reflection.

In other words, an aspect of the present invention is a photoelectric conversion module including a protective layer, photoelectric conversion cells provided over the protective layer, and a reflection member provided over the protective layer in a space between the photoelectric conversion cells or at a periphery of the photoelectric conversion cell, wherein a cross-sectional shape of the reflection member taken perpendicularly from a peak portion thereof to the protective layer is substantially triangular with the peak portion in a light incidence direction, that is the peak portion is higher than a surface of the photoelectric conversion cells, wherein a surface of the reflection member has a visible light reflectance of 70% or more and an infrared light reflectance of 70% or more, and wherein the peak portion of the reflection member is on a light incidence direction side as compared with a surface of the photoelectric conversion cell.

According to the above aspect of the present invention, the incident light which does not contribute to power generation under normal circumstances can be reflected by the reflection member so that the light can be guided to the photoelectric conversion cell by one-time reflection. Accordingly, a photoelectric conversion module which generates a large amount of electric power can be provided.

Further, an aspect of the present invention is a photoelectric conversion module including a protective layer, photoelectric conversion cells provided over the protective layer, a sealing layer for covering the photoelectric conversion cells, and a reflection member provided over the sealing layer, wherein a cross-sectional shape of the reflection member taken perpendicularly from a peak portion thereof to the protective layer is substantially triangular with the peak portion in a light incidence direction, that is the peak portion is higher than a surface of the photoelectric conversion cells, wherein a surface of the reflection member has a visible light reflectance of 70% or more and an infrared light reflectance of 70% or more, and wherein a space between the photoelectric conversion cells or a periphery of the photoelectric conversion cell overlaps with the reflection member.

According to the above aspect of the present invention, even though the reflection member is provided so as to overlap with the photoelectric conversion cell, an insulated state between the photoelectric conversion cell and the reflection member can be maintained due to the sealing layer. Thus, a photoelectric conversion module which generates a large amount of electric power can be provided without lowering a yield.

Further, an aspect of the present invention is the photoelectric conversion module wherein an intersecting angle between the protective layer and a straight line connecting the peak portion of the reflection member and an end portion of a bottom of the reflection member that is closest to the peak portion is more than 45° and less than 90°.

According to the above aspect of the present invention, the incident light reflected by the reflection member can be guided to the photoelectric conversion cell efficiently. Therefore, a photoelectric conversion module which generates a large amount of electric power can be provided.

Moreover, an aspect of the present invention is the photoelectric conversion module wherein an area where the reflection member overlaps with the photoelectric conversion cell is smaller than an area where the reflection member overlaps with the space between the photoelectric conversion cells or the periphery of the photoelectric conversion cell.

According to the above aspect of the present invention, the amount of increase in power generation by the provision of the reflection member is larger than the amount of decrease in power generation by the overlap between the reflection member and the photoelectric conversion cell. Therefore, a photoelectric conversion module which generates a large amount of electric power can be provided.

An aspect of the present invention is the photoelectric conversion module wherein the reflection member is detachable.

According to the above aspect of the present invention, the reflection member can be exchanged when the performance of the reflection member has lowered due to deterioration over time or damage. Therefore, a photoelectric conversion module in which a decrease in amount of electric power to be generated is suppressed can be provided.

An aspect of the present invention is a photoelectric conversion device which has a function of automatically controlling an angle of the photoelectric conversion module by sequentially tracking a position of a light source.

According to the above aspect of the present invention, a decrease in amount of electric power to be generated, which is caused when a shadow of the reflection member falls on the photoelectric conversion cell, can be suppressed. Therefore, a photoelectric conversion device which generates a large amount of electric power can be provided.

When “B is formed on A” or “B is formed over A” is explicitly described in this specification, it does not necessarily mean that B is formed in direct contact with A. The expression includes the case where A and B are not in direct contact with each other, i.e., the case where another object is interposed between A and B. Here, each of A and B corresponds to an object (e.g., a device, an element, a circuit, a wiring, an electrode, a terminal, a film, or a layer).

Therefore, for example, when it is explicitly described that a layer B is formed on or over a layer A, it includes both the case where the layer B is formed in direct contact with the layer A and the case where another layer (e.g., a layer C or a layer D) is formed in direct contact with the layer A and the layer B is formed in direct contact with the layer C or the layer D. Note that another layer (e.g., a layer C or a layer D) may be a single layer or a plurality of layers.

Moreover, in a manner similar to the above, when “periphery of A is covered with B” is explicitly described in this specification, it includes both the case where B is formed in direct contact with the periphery of A and the case where another object is interposed between B and the periphery of A.

Note that “photoelectric conversion layer” in this specification includes in its category a semiconductor layer by which a photoelectric (internal photoelectric) effect is achieved and moreover an impurity semiconductor layer bonded for forming an internal electric field or a semiconductor junction. That is, a semiconductor layer in which a plurality of semiconductor layers with different carrier concentrations are bonded, typically pn junction, is included in the category of the photoelectric conversion layer.

Further, “photoelectric conversion cell” in this specification refers to one photoelectric conversion cell which contributes to power generation and, for example, has a structure including a semiconductor layer provided with pn junction and upper and lower electrodes. Moreover, “photoelectric conversion module” refers to a structure in which a plurality of photoelectric conversion cells are electrically connected in series and/or in parallel through a connection wiring. In addition, “photoelectric conversion device” refers to a structure including a mechanism for driving a photoelectric conversion module in addition to the photoelectric conversion module.

Note that in this specification, the ordinal number such as “first”, “second”, “third”, or “fourth” is given for convenience to distinguish elements, and not given to limit the number, the arrangement, and the order of the steps.

In this specification, moreover, light which directly enters a photoelectric conversion cell is referred to as “direct incident light”, and light which indirectly enters a photoelectric conversion cell via a reflection member or the like is referred to as “indirect incident light”.

Furthermore, although this specification includes the expression “visible light reflectance is X% or more”, this does not necessarily mean “reflectance is X % or more over the entire visible light region” as long as the reflectance is X% or more in a part of a visible light region. This similarly applies to the expression “infrared light reflectance is Y% or more.”

According to the present invention, it is possible to provide a photoelectric conversion module which generates a large amount of electric power and which can convert into electricity even light which enters a region not provided with a photoelectric conversion cell. Further, a photoelectric conversion module in which a decrease in amount of electric power to be generated is suppressed can be provided. Furthermore, a photoelectric conversion device which generates a large amount of electric power can be provided.

### BRIEF DESCRIPTION OF THE DRAWINGS

In the accompanying drawings:

FIGS. 1A and 1B are for explaining a structure of a photoelectric conversion module according to an embodiment of the present invention;

FIGS. 2A and 2B are for explaining a structure of the photoelectric conversion cell according to an embodiment of the present invention;

FIGS. 3A to 3D are each for explaining a structure of a reflection member according to an embodiment of the present invention and FIG. 3E is for explaining structures of a reflection member, a sealing resin, a photoelectric conversion cell and the protective layer according to an embodiment of the present invention;

FIGS. 4A and 4B are each for explaining an effect of a photoelectric conversion module according to an embodiment of the present invention;

FIGS. 5A and 5B are for explaining a structure of a photoelectric conversion module according to an embodiment of the present invention;

FIG. 6 is for explaining a structure of a photoelectric conversion cell according to an embodiment of the present invention;

FIGS. 7A and 7B are each for explaining an effect of a photoelectric conversion module according to an embodiment of the present invention; and

FIGS. 8A and 8B are each for explaining an application mode of a photoelectric conversion device including a photoelectric conversion module according to the present invention.

### DETAILED DESCRIPTION OF THE INVENTION

Embodiments of the present invention will be described in detail with reference to the drawings. Note that the invention is not limited to the following description, and it will be easily understood by those skilled in the art that various changes and modifications can be made without departing from the spirit and scope of the invention. Therefore, the present invention should not be construed as being limited to the description in Embodiments below. Note that in the structures of the invention described below, the same portions or portions having similar functions are denoted by the same reference numerals in different drawings, and description of such portions is not repeated.

### Embodiment 1

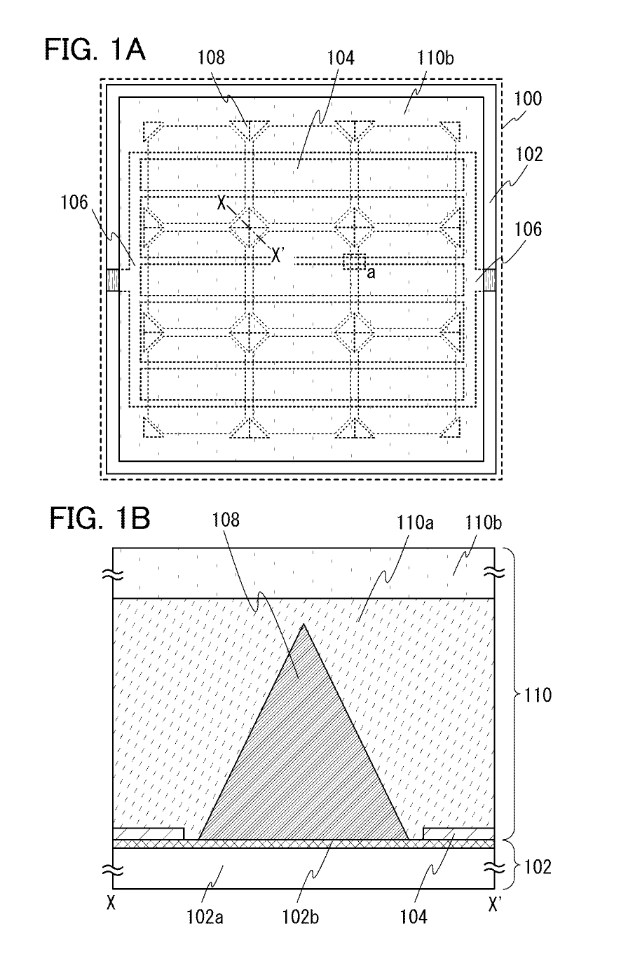

With reference to FIGS. 1A and 1B, FIGS. 2A and 2B, FIGS. 3A to 3E, and FIGS. 4A and 4B, Embodiment 1 will describe a photoelectric conversion module according to an aspect of the invention to be disclosed.

### Structure of Photoelectric Conversion Module in Embodiment 1

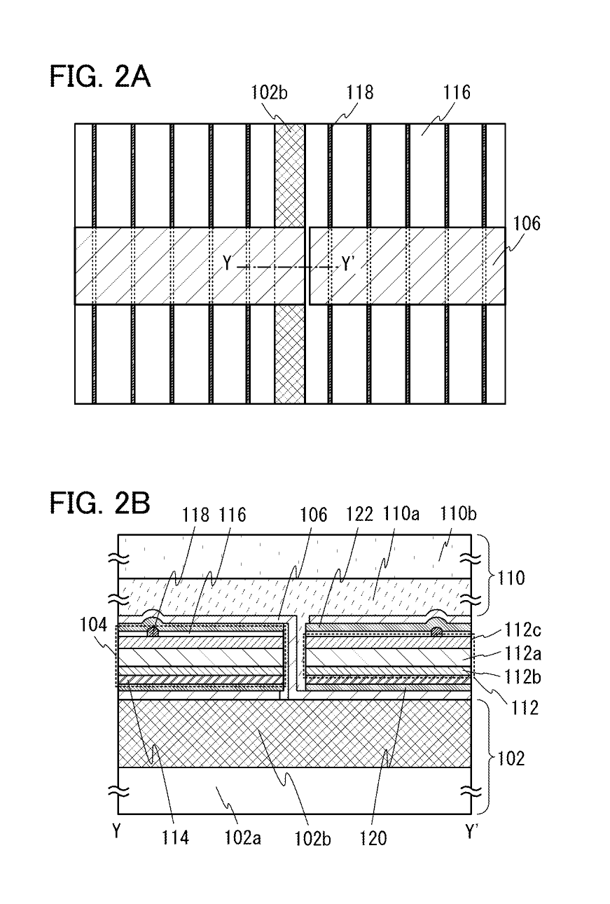

An example of a structure diagram of a photoelectric conversion module in Embodiment 1 is shown in FIGS. 1A and 1B and FIGS. 2A and 2B. FIG. 1A is an example of a schematic planar view of a photoelectric conversion module in which a plurality of photoelectric conversion cells are provided over one substrate and are connected in series and/or in parallel. FIG. 1B is a schematic cross-sectional view taken along a long dashed short dashed line X1-X2 in FIG. 1A. Note that some components of the photoelectric conversion module (a protective base 102a, for example) are omitted in FIG. 2A in order to avoid complication.

FIG. 2A is an expanded view of a portion (portion “a”) surrounded by a long dashed double-short dashed line in FIG. 1A, and FIG. 2B is a schematic cross-sectional view taken along a long dashed short dashed line Y1-Y2 in FIG. 2A.

Note that the number of photoelectric conversion cells provided over the protective layer, the area of the photoelectric conversion cell, the method for connecting the photoelectric conversion cells in series or in parallel, the method for extracting electric power from the photoelectric conversion module, and the like are optional, and can be determined depending on desired amount of electric power (and current, voltage), an installation location, or the like by a person who carries out this invention.

A photoelectric conversion module 100 of Embodiment 1 includes, as shown in FIGS. 1A and 1B, a protective layer 102, photoelectric conversion cells 104 arranged with a predetermined interval therebetween, a connection wiring 106, a reflection member 108 provided for a space between the photoelectric conversion cells 104 or a periphery of the photoelectric conversion cell 104, and a sealing layer 110 for covering the photoelectric conversion cell 104 and the reflection member 108.

The protective layer 102 includes at least a protective base 102a, and may further include a protective resin 102b in contact with the protective base 102a. For the protective base 102a, for example, any of a variety of plastic substrates including ethylene vinyl acetate (EVA), a polyethylene terephthalate resin (PET), a polyether sulfone resin (PES), a polyethylene naphthalate resin (PEN), a polyvinyl alcohol resin (PVA), a polycarbonate resin (PC), a polyethylene resin (PE), an ABS resin, and the like; a metal substrate such as an aluminum substrate, a stainless steel substrate, or a copper substrate provided with an insulating film on its surface; any of a variety of glass substrates including a general flat glass, a clear flat glass, a lead glass, a tempered glass, a ceramic glass, and the like; a quartz substrate; a ceramic substrate; a sapphire substrate; or the like can be used. A base other than those above can also be used without particular limitation as long as the base can withstand a fabrication process of a photoelectric conversion module according to an aspect of the present invention. In the case where light enters also from the protective layer 102 side, it is preferable to use a base with a visible light transmittance of 80% or more, more preferable to use a base with a light-transmitting property of 90% or more as the protective base 102a.

For the protective resin 102b, for example, any of the following organic resin materials can be used: ethylene vinyl acetate (EVA), a polyethylene terephthalate resin (PET), a polyether sulfone resin (PES), a polyethylene naphthalate resin (PEN), a polyvinyl alcohol resin (PVA), a polycarbonate resin (PC), a nylon resin, an acrylic resin, a polyacrylonitrile resin, a polyetheretherketone resin (PEEK), a polystyrene resin (PS), a polysulfone resin (PSF), a polyetherimide resin (PEI), a polyarylate resin (PAR), a polybutylene terephthalate resin (PBT), a polyimide resin (PI), a polyamide resin (PA), a polyamide imide resin (PAI), a polyisobutylene resin (PIB), a chlorinated polyether resin (CP), a melamine resin (MF), an epoxy resin (EP), a poly vinylidene chloride resin (PVDC), a polypropylene resin (PP), a polyacetal resin (POM), a phenol resin (PF), a furan resin (FF), an unsaturated polyester resin (UP), a cellulose acetate resin (CA), a urea resin (LT), a xylene resin (XR), a diallyl phthalate resin (DAP), a polyvinyl acetate resin (PVAc), a polyethylene resin (PE) , a fluoro resin, and an ABS resin. A resin material other than those above can be also used without particular limitation as long as the resin material can withstand a fabrication process of a photoelectric conversion module according to an aspect of the present invention. In the case where light enters also from the protective layer 102 side, it is preferable to use a resin material with a visible light transmittance of 80% or more, more preferable to use a resin material with a visible light transmittance of 90% or more as the protective resin 102b.

There is no particular limitation on the shape or installation condition of the photoelectric conversion cell 104; however, it is desirable to set the photoelectric conversion cells 104 so that the space between the photoelectric conversion cells 104 when the photoelectric conversion cells 104 are provided over the protective layer 102 is small. However, for example, in a photoelectric conversion cell fabricated using a single-crystal silicon wafer, a polygonal single-crystal silicon wafer obtained by removing parts of an end of a circular silicon wafer manufactured by slicing a silicon ingot is used. Therefore, a space is formed even in the case where the photoelectric conversion cells are provided over the protective layer efficiently. When this space is provided with the reflection member 108 as shown in FIG. 1A, the area which does not contribute to power generation can be decreased and the amount of electric power to be generated by the photoelectric conversion module can be increased.

The photoelectric conversion cell 104 has a structure including, as shown in FIG. 2B, a photoelectric conversion layer 112 having a function of receiving light energy (e.g., sunlight) having entered from outside and converting the light energy into electric energy, a first electrode 114 provided in contact with one plane of the photoelectric conversion layer 112, a conduction prevention layer 116 provided in contact with another plane of the photoelectric conversion layer 112, and a second electrode 118 which penetrates through the conduction prevention layer 116 and which is electrically connected to the photoelectric conversion layer 112. The photoelectric conversion cells 104 are electrically connected to each other by the connection wiring 106 via a first conductive material 120 provided between the first electrode 114 and the protective layer and via a second conductive material 122 electrically connected to the second electrode. Note that a part of the connection wiring 106 also functions as an external connection terminal for connecting an external device (such as a power conditioner or a power storage device) and the photoelectric conversion module.

The photoelectric conversion layer 112 in Embodiment 1 has a structure including, as shown in FIG. 2B, three layers of a first semiconductor layer 112a positioned at a center of the photoelectric conversion layer 112, a second semiconductor layer 112b provided for one plane of the first semiconductor layer 112a, and a third semiconductor layer 112c provided for another plane of the first semiconductor layer 112a.

For example, for the first semiconductor layer 112a, crystalline silicon (such as single-crystal silicon, polycrystalline silicon, or microcrystalline silicon) or amorphous silicon can be used. Alternatively, a material containing crystalline silicon and amorphous silicon, a silicon material containing nitrogen or carbon, or the like can be used.

The second semiconductor layer 112b and the third semiconductor layer 112c can be formed by adding an impurity element imparting conductivity type to the first semiconductor layer 112a by a thermal diffusion method, an ion doping method, or the like. As an impurity imparting p-type conductivity, boron or aluminum which is an element belonging to Group 13 in the periodic table or the like is given. As an impurity imparting n-type conductivity, phosphorus, arsenic, or antimony which is an element belonging to Group 15 in the periodic table, or the like is given.

Instead of the above formation method, a PECVD method, a thermal CVD method, or a sputtering method may be employed for forming the photoelectric conversion layer 112 by stacking the first semiconductor layer 112a, the second semiconductor layer 112b, and the third semiconductor layer 112c.

The photoelectric conversion layer 112 in Embodiment 1 has a three-layer structure in which a p-type single-crystal silicon wafer is used as the first semiconductor layer 112a, the second semiconductor layer 112b is formed by adding an impurity element imparting p-type conductivity to one plane of the first semiconductor layer 112a, and the third semiconductor layer 112c is formed by adding an impurity element imparting n-type conductivity to another plane of the first semiconductor layer 112a.

The structure of the photoelectric conversion layer 112 is not limited to the above structure as long as the photoelectric conversion layer 112 is a layer having a photoelectric effect formed by including at least one p-type semiconductor layer and at least one n-type semiconductor layer. As an alternative to the silicon material, a compound semiconductor such as CIGS (Cu(In,Ga)Se₂) or CdTe, or a compound semiconductor including an element belonging to any of Group III to Group V may be used.

The first electrode 114 can be formed by for example, a single layer or a stack of layers including a metal material such as aluminum, silver, nickel, copper, tin, titanium, molybdenum, tungsten, tantalum, or chromium, or an alloy or paste material including any of those metal materials by a printing method, an evaporation method, a sputtering method, or the like.

The conduction prevention layer 116 can be formed by, for example, a single layer or a stack of layers including silicon oxide, silicon oxynitride, silicon nitride, silicon nitride oxide, or titanium oxide by a chemical vapor deposition method (CVD method), a sputtering method, or the like. Note that the conduction prevention layer 116 preferably has a function as an antireflection film for preventing reflection of incident light. This makes it possible to suppress the reflection of incident light which occurs at the conduction prevention layer 116 and to increase the amount of electric power to be generated by the photoelectric conversion module.

The second electrode 118, the first conductive material 120, and the second conductive material 122 may be formed using, for example, a paste material including nickel, aluminum, silver, or solder, a lead-free solder, or the like by a printing method, a dropping method, a coating method, or the like. Note that the second electrode 118 is formed in such a state that the second electrode 118 is embedded in the conduction prevention layer 116 in FIG. 2B (hereinafter the second electrode 118 is referred to as an embedded electrode). As an example of a method for manufacturing such an embedded electrode, there is a method in which after the second electrode 118 is formed over the conduction prevention layer 116 by a printing method, a dropping method, a coating method, or the like, heat treatment is performed thereon, so that the second electrode 118 penetrates through the conduction prevention layer 116 by diffusing the composition of the second electrode 118 into the conduction prevention layer 116 (this method is also referred to as fire through or baking penetration).

For the connection wiring 106, for example, a tin-plated copper wiring, a solder-plated copper wiring, or a metal foil such as an aluminum foil, a silver foil, a copper foil, a nickel foil, or a tin foil can be used. Alternatively, a paste material including nickel, aluminum, silver, solder, or the like, solder, or the like can be formed as a leading wiring by a printing method, a dropping method, or the like. Note that the connection wiring 106 is preferably attached to the photoelectric conversion cell 104 by the first conductive material 120 and the second conductive material 122.

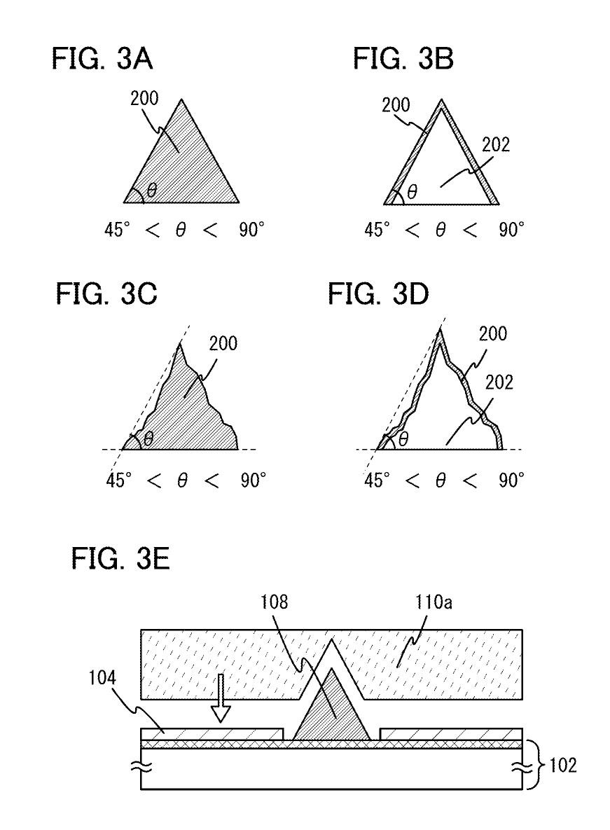

The reflection member 108 includes a material which reflects incident light, and is formed over a plane which is not in direct contact with the protective layer 102 (corresponding to a portion illustrated with oblique lines in FIG. 1B). An intersecting angle between the protective layer and a straight line connecting a peak portion of the reflection member 108 and an end portion of a bottom of the reflection member 108 (angle θ in FIG. 3A) is more than 45° and less than 90°. For example, as shown in FIG. 3A, a structure in which the entire reflection member 108 is formed of a reflection material 200 can be employed. Note that the structure shown in each of FIGS. 3A to 3D is an example of the reflection member 108.

As the material used for the reflection material 200, for example, aluminum (Al), silver (Ag), gold (Au), chromium (Cr), nickel (Ni), platinum (Pt), tin (Sn), copper (Cu), tungsten (W), or an alloy including any of those is given. In order to increase the reflectance, a surface thereof may be covered with silicon oxide, silicon oxynitride, silicon nitride, silicon nitride oxide, or the like. The reflection material 200 is not limited to the above material and there is no particular limitation as long as the visible light reflectance and the infrared light reflectance of the material are 70% or more.

Further, as shown in FIG. 3B, a structure in which a surface of a base 202 is provided with the reflection material 200 may be employed. By the provision of the reflection material 200 for only the surface of the base 202, the reflection member 108 can be manufactured at low cost. The reflection material 200 can be formed by a sputtering method, a vacuum evaporation method, a chemical vapor deposition (CVD) method, a plating treatment, or the like. Alternatively, a material functioning as the reflection material 200 can be directly applied over the surface of the base 202.

As the material of the base 202, for example, an inexpensive material such as a variety of resins or glasses may be used, and the base 202 may be manufactured using an apparatus capable of mass production such as a mold. Since this makes it possible to decrease the cost of the reflection member 108, the amount of electric power to be generated by the photoelectric conversion module can be increased without a drastic increase in cost.

Further, since the cross-sectional shape of the reflection member 108 may be substantially triangular, the reflection member 108 may have a structure entirely formed of the reflection material 200 with an uneven surface as shown in FIG. 3C or a structure including the reflection material 200 over an uneven surface of the base 202 as shown in FIG. 3D.

In Embodiment 1, although the shape of the reflection member 108 differs in the space portion between the photoelectric conversion cells and at the periphery of the photoelectric conversion cell as shown in FIG. 1A, the present invention is not limited to this. For example, the reflection member 108 with the shape thereof provided for the space portion between the photoelectric conversion cells may be provided for the periphery of the photoelectric conversion cell.

The sealing layer 110 includes at least a sealing resin 110a, and may further include a sealing base 110b in contact with the sealing resin 110a. For the sealing resin 110a, for example, any of the following organic resin materials can be used: ethylene vinyl acetate (EVA), a polyethylene terephthalate resin (PET), a polyether sulfone resin (PES), a polyethylene naphthalate resin (PEN), a polyvinyl alcohol resin (PVA), a polycarbonate resin (PC), a nylon resin, an acrylic resin, a polyacrylonitrile resin, a polyetheretherketone resin (PEEK), a polystyrene resin (PS), a polysulfone resin (PSF), a polyetherimide resin (PEI), a polyarylate resin (PAR), a polybutylene terephthalate resin (PBT), a polyimide resin (PI), a polyamide resin (PA), a polyamide imide resin (PAI), a polyisobutylene resin (PIB), a chlorinated polyether resin (CP), a melamine resin (MF), an epoxy resin (EP), a poly vinylidene chloride resin (PVDC), a polypropylene resin (PP), a polyacetal resin (POM), a phenol resin (PF), a furan resin (FF), an unsaturated polyester resin (UP), a cellulose acetate resin (CA), a urea resin (UF), a xylene resin (XR), a diallyl phthalate resin (DAP), a polyvinyl acetate resin (PVAc), a polyethylene resin (PE), a fluoro resin, and an ABS resin. The sealing resin 110a preferably includes a resin material having a visible light transmittance of 80% or more, more preferably a light transmittance of 90% or more. A resin material other than those above can be also used without particular limitation as long as the resin material can withstand a fabrication process of a photoelectric conversion module according to an aspect of the present invention.

Any of a variety of films including the above resin materials may be used as the sealing resin 110a. In this case, in order to avoid the formation of a space between the photoelectric conversion cell 104 and the sealing layer 110, the sealing resin 110a is preferably provided with a depressed portion which is similar to the shape of the reflection member 108 as shown in FIG. 3E and the photoelectric conversion cell 104 and the sealing resin 110a are preferably attached to each other by welding through heat treatment or the like. Alternatively, after the reflection member 108 is embedded in the sealing resin 110a provided with the depressed portion, the photoelectric conversion cell 104 and the protective layer 102 may be attached to the reflection member 108 and the sealing resin 110a.

As the sealing base 110b, any of a variety of glass substrates or a variety of plastic substrates including a polyethylene terephthalate resin (PET), a polyether sulfone resin (PES), a polyethylene naphthalate resin (PEN), a polyvinyl alcohol resin (PVA), a polycarbonate resin (PC), a polyethylene resin (PE), an ABS resin, and the like can be used.

By covering the periphery of the photoelectric conversion cells 104 with the sealing resin 110a and the protective resin 102b, the intrusion of gas components, moisture, and dust from outside into the photoelectric conversion cells can be suppressed. Furthermore, an external physical impact on the photoelectric conversion cells can be decreased. Accordingly, deterioration of performance of the photoelectric conversion cells 104 can be suppressed.

Note that the sealing layer 110 preferably has a visible light transmittance and an infrared light transmittance of 80% or more, more preferably has a light transmittance of 90% or more.

### Effect of Photoelectric Conversion Module in Embodiment 1

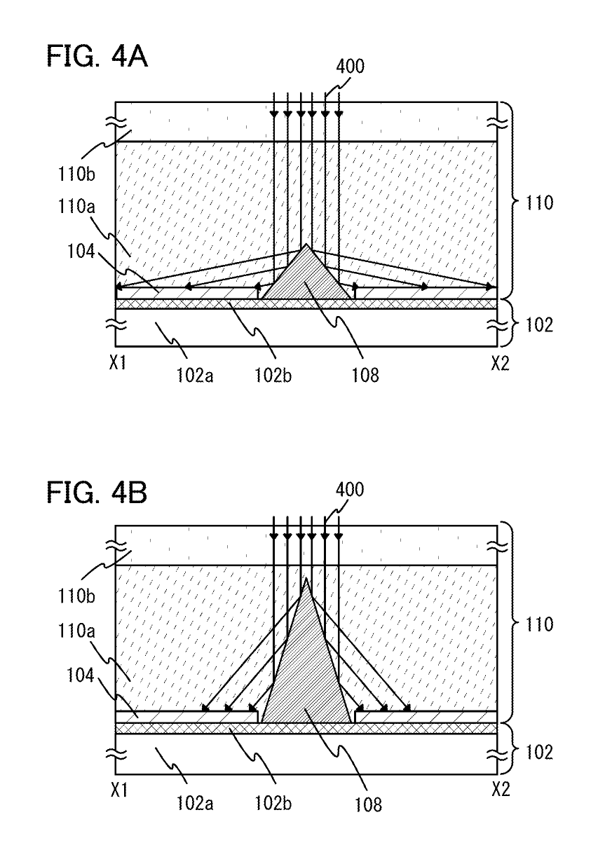

FIGS. 4A and 4B each show a route of incident light when light enters from outside the photoelectric conversion module having the structure of Embodiment 1. Incident light 400 having entered the space between the photoelectric conversion cells or the periphery of the photoelectric conversion cell is reflected by an oblique plane of the reflection member 108 and is guided to the photoelectric conversion cell 104. Since the peak portion of the reflection member 108 is on the light incidence direction side as compared with a surface of the photoelectric conversion cell 104, that is the peak portion is higher than a surface of the photoelectric conversion cell 104, in the photoelectric conversion module 100 with the structure described in Embodiment 1, the incident light reaches the photoelectric conversion cell 104 through the reflection at the oblique plane of the reflection member 108. In order to effectively guide to the photoelectric conversion cell 104 the incident light 400 having entered the space between the photoelectric conversion cells or the periphery of the photoelectric conversion cell, an intersecting angle between the protective layer and a straight line connecting the peak portion of the reflection member 108 and an end portion of a bottom of the reflection member 108 (angle θ in FIG. 3A) may be more than 45° and less than 90°.

Note that the distance of the incident light travelling in the sealing layer 110 can be decreased by increasing the tilt angle of the reflection member 108 as shown in FIG. 4B in comparison with that of FIG. 4A. Although it depends on the material, the sealing layer 110 has a property of absorbing light in an ultraviolet light region, a visible light region, or an infrared light region more than a little; therefore, by decreasing the distance of the incident light 400 travelling in the sealing layer 110, the loss of light due to the light absorption by the sealing layer 110 can be suppressed and the amount of electric power to be generated by the photoelectric conversion module 100 can be increased. Although the reflection member 108 is provided so as not to be exposed beyond a surface of the sealing layer 110 in FIGS. 4A and 4B, the present invention is not particularly limited to this.

In this manner, by the use of the structure of Embodiment 1 for the photoelectric conversion module, the photoelectric conversion module can be provided to have high efficiency.

The photoelectric conversion module as shown in Embodiment 1 in which the peak portion of the reflection member 108 is provided on the incident light side as compared with the surface of the photoelectric conversion cell 104, that is the peak portion is higher than a surface of the photoelectric conversion cell 104, has a possibility of generating a smaller amount of electric power because a part of the photoelectric conversion cell 104 is shadowed by the reflection member 108 depending on the angle of the incident light.

When a photoelectric conversion device is manufactured using the photoelectric conversion module 100 described in Embodiment 1, it is preferable for the photoelectric conversion device to have a function of automatically controlling the angle of the photoelectric conversion module 100 by sequentially tracking the position of a light source in order for a part of the photoelectric conversion cell 104 not to be shadowed by the reflection member 108. This can suppress a decrease in amount of electric power to be generated by the photoelectric conversion device due to the shadow of the reflection member 108. As such a function of tracking the light source, for example, a method is given in which two or more devices having a function of detecting the amount of light (hereinafter referred to as a light amount detecting device) such as a photosensor are provided for the photoelectric conversion module and the angle of the photoelectric conversion module 100 is controlled to be an appropriate angle by comparing the amounts of detection in the respective light amount detection devices (that is, an angle at which the shadow of the reflection member 108 is formed as little as possible). Known various techniques can be used as the function of tracking the light source without particular limitation to the above example.

### Embodiment 2

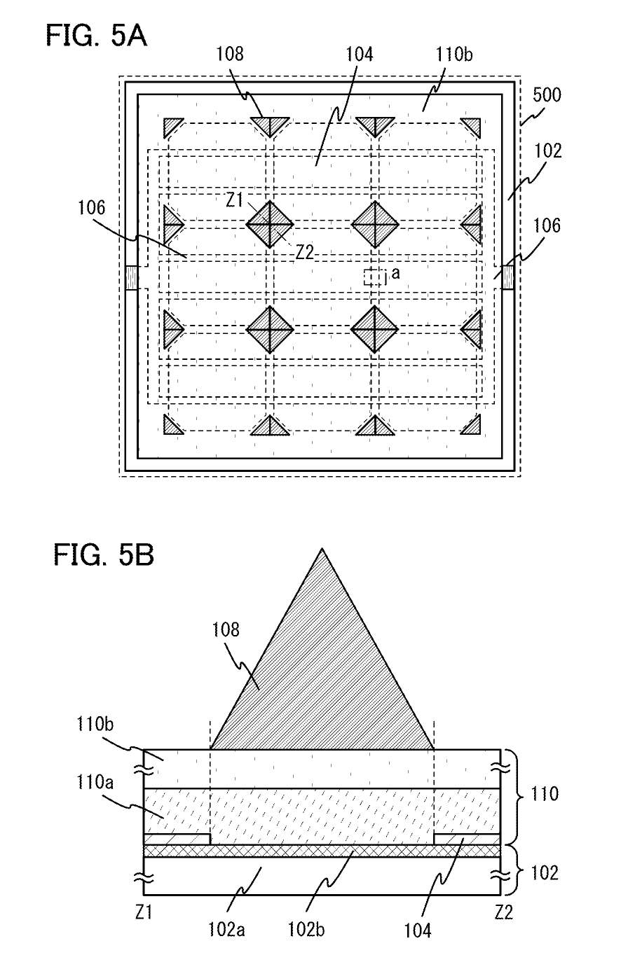

With reference to FIGS. 5A and 5B, FIG. 6, and FIGS. 7A and 7B, Embodiment 2 will describe a photoelectric conversion module whose structure is partly different from that of the aspect of the present invention described in Embodiment 1.

### Structure of Photoelectric Conversion Module of Embodiment 2

FIGS. 5A and 5B are structure diagrams of a photoelectric conversion module of Embodiment 2. FIG. 5A is a top view of the photoelectric conversion module of Embodiment 2 and is a schematic plan view of the photoelectric conversion module in which a plurality of photoelectric conversion cells are provided over one substrate and the plurality of photoelectric conversion cells are connected in series and/or in parallel. FIG. 5B shows an example of a schematic cross-sectional view taken along a long dashed short dashed line Z1-Z2 of FIG. 5A. Since a portion surrounded by a long dashed double-short dashed line in FIG. 5A (portion “a”) is the same as that in FIG. 2A, the description is omitted here.

A photoelectric conversion module 500 in Embodiment 2 includes, as shown in FIGS. 5A and 5B, the protective layer 102, the photoelectric conversion cells 104 provided with a predetermined interval therebetween, the connection wiring 106, the sealing layer 110 provided so as to cover the photoelectric conversion cells 104, and the reflection member 108 provided over the sealing layer 110 in a space between the photoelectric conversion cells 104 or at a periphery of the photoelectric conversion cell 104. Note that since the details of the component elements are the same as those of Embodiment 1, the description is omitted here.

The photoelectric conversion module 500 of Embodiment 2 has a structure in which the reflection member 108 is provided over the sealing layer 110 as shown in FIG. 5B.

The photoelectric conversion cell 104 is provided with, as shown in FIG. 2B, the second electrode 118, the second conductive material 122, and the connection wiring 106 on its surface. Therefore, the surface of the photoelectric conversion cell 104 is conductive. In the case where a conductive material such as aluminum is used as the reflection material 200 of the reflection member 108, the surface is conductive. Therefore, in the case where the reflection member 108 is provided for the space between the photoelectric conversion cells or the periphery of the photoelectric conversion cell as in Embodiment 1, it is necessary to dispose the reflection member 108 with a space ensured between the reflection member 108 and the photoelectric conversion cell 104 so that the reflection member 108 and the photoelectric conversion cell 104 are not in contact with each other.

Since the sealing layer 110 is provided over the photoelectric conversion cell 104 and the reflection member 108 is provided over the sealing layer 110 in Embodiment 2, an insulated state between the photoelectric conversion cell 104 and the reflection member 108 can be maintained even though the reflection member 108 is provided so as to overlap with the photoelectric conversion cell 104. Therefore, in the photoelectric conversion module 500 shown in Embodiment 2, the area of the space between the photoelectric conversion cells 104 can be made the same as the bottom area of the reflection member 108 as in FIGS. 5A and 5B. Thus, the amount of electric power to be generated by the photoelectric conversion module can be increased without decreasing the production yield of the photoelectric conversion module.

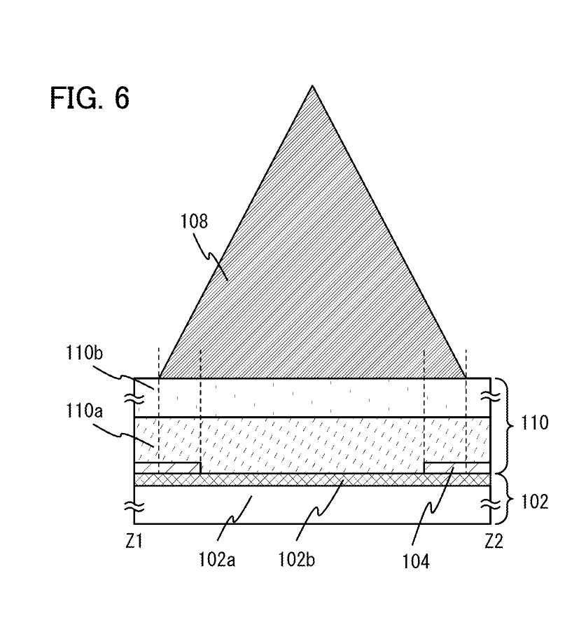

Note that in the case where the reflection member is also used for another photoelectric conversion module in which the space between the photoelectric conversion cells is larger than that in Embodiment 2, it is sometimes necessary that the photoelectric conversion module in Embodiment 2 includes the reflection member 108 with a larger bottom area than the area of the space between the photoelectric conversion cells 104 as shown in FIG. 6. In this case, the amount of electric power to be generated by the photoelectric conversion module 500 can be increased by setting α<β where a is the area where the reflection member 108 overlaps with the photoelectric conversion cell 104 and 3 is the area where the reflection member 108 overlaps with the space between the photoelectric conversion cells 104 or the periphery thereof In this manner, since the reflection member can be used commonly among the plural photoelectric conversion modules, the manufacturing cost of the reflection member can be decreased.

As a method for providing the reflection member 108 over the sealing layer 110, for example, an adhesive tape such as a double-sided tape or any of a variety of adhesives may be used for fixture, and having a water-resistant property is desired. In the case where both the bottom surface of the reflection member 108 and the surface of the sealing layer 110 have high smoothness and adhesion is possible by pressing the both to each other (also called vacuum adhesion), the adhesive tape or the adhesive is not necessarily used.

The reflection member 108 may be provided so as to be detachable as necessary even after fixture by a person who carries out this invention. This makes it possible to replace the reflection member 108 when the performance of the reflection member 108 has lowered due to deterioration over time or damage. Therefore, a decrease in amount of electric power to be generated by the photoelectric conversion module 500 can be suppressed. As the method for providing the reflection member 108 so as to be detachable, for example, the use of an adhesive and an adhesive tape having weak stickiness capable of being peeled by a physical force of such a degree that the sealing layer 110 is not damaged, e.g., not deformed or not cracked; an adhesive and an adhesive tape whose stickiness decreases by irradiation with light with a particular wavelength; or the like is given.

### Effect of Photoelectric Conversion Module in Embodiment 2

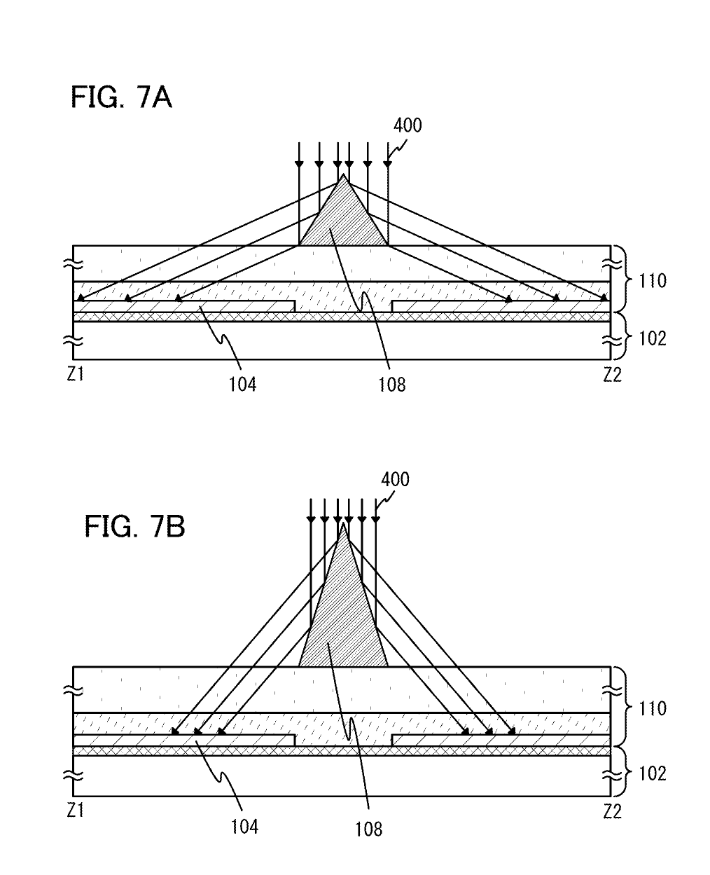

FIGS. 7A and 7B each show a route of incident light when the light enters from outside the photoelectric conversion module 500 having a structure of Embodiment 2. The incident light 400 having entered the space between the photoelectric conversion cells 104 or the periphery of the photoelectric conversion cell 104 is reflected by the oblique plane of the reflection member 108 and is guided to the photoelectric conversion cell 104. Since the peak portion of the reflection member 108 is on the light incidence direction side as compared with the surface of the photoelectric conversion cell 104, that is the peak portion is higher than a surface of the photoelectric conversion cell 104, in the photoelectric conversion module 500 described in Embodiment 2, the incident light reaches the photoelectric conversion cell 104 through the reflection only at the oblique plane of the reflection member 108.

The distance of the incident light 400 travelling through the sealing layer 110 can be decreased by increasing the tilt angle of the reflection member 108 in FIG. 7B in comparison with that in FIG. 7A. Although it depends on the material, the sealing layer 110 has a property of absorbing light in an ultraviolet light region, a visible light region, or an infrared light region more than a little; therefore, by decreasing the distance of the incident light travelling in the sealing layer 110, the amount of electric power to be generated by the photoelectric conversion module 500 can be increased.

Thus, by the use of the structure of Embodiment 2 for the photoelectric conversion module, the photoelectric conversion module can be provided to have high efficiency

The photoelectric conversion module 500 as shown in Embodiment 2 in which the peak portion of the reflection member 108 is on the incident light side as compared with the surface of the photoelectric conversion cell 104, that is the peak portion is higher than a surface of the photoelectric conversion cell 104, has a possibility of generating a smaller amount of electric power because a part of the photoelectric conversion cell 104 is shadowed by the reflection member 108 depending on the angle of the incident light. Therefore, a function of tracking a light source is desirably added in a manner similar to Embodiment 1.

### Embodiment 3

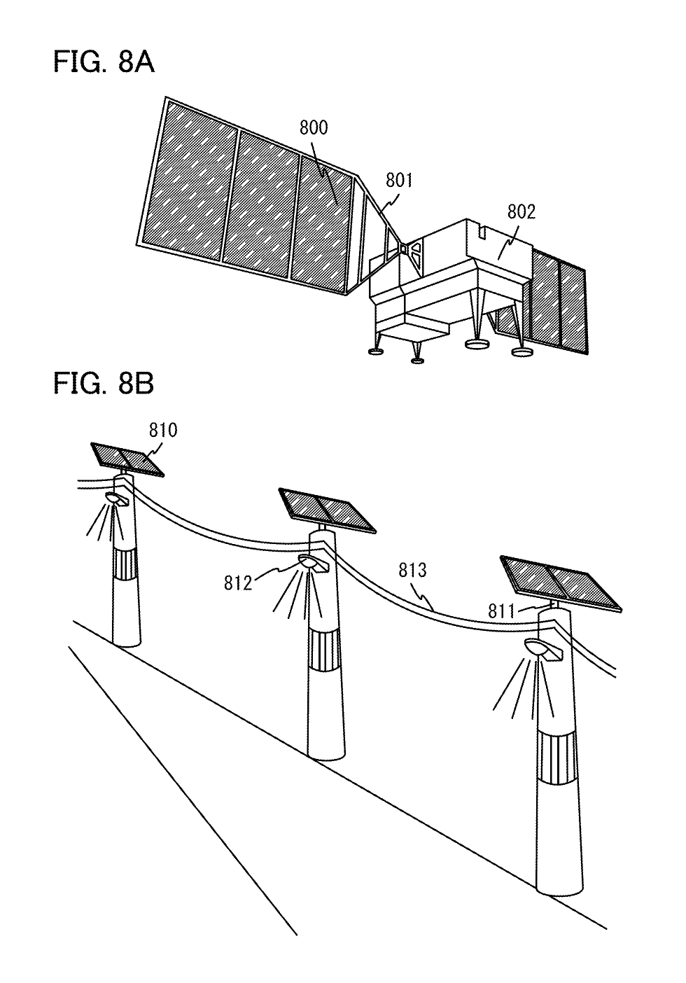

Embodiment 3 will describe examples of an application mode of a photoelectric conversion module according to the present invention. Specific examples of devices each including a photoelectric conversion module according to the present invention are hereinafter described with reference to FIGS. 8A and 8B. Note that only an artificial satellite and an illumination-equipped utility pole each provided with the photoelectric conversion module are described as the specific examples in Embodiment 3; however, all devices each provided with the photoelectric conversion module according to the present invention and having a function of using or storing electricity generated by the photoelectric conversion module can be regarded as the device including the photoelectric conversion module.

FIG. 8A shows an artificial satellite including a photoelectric conversion module 800 and a photoelectric conversion module fixture mechanism 801, and a part of or all parts of an artificial satellite unit 802 are operated using electric power generated by the photoelectric conversion module 800. The photoelectric conversion module 800 has the mechanism described in this specification, and generates a large amount of electric power because the incident light can be converted into electricity efficiently. Therefore, since a large amount of electric power can be obtained stably, a variety of appliances necessary for planetary inspection or the like can be incorporated into the artificial satellite unit 802. Note that in the case where the photoelectric conversion module according to the present invention is used under a severe environment like the artificial satellite, the structure in which the reflection member is covered with the sealing layer as shown in Embodiment 1 is preferable. This makes it possible to suppress deterioration of the reflection member due to collision of space debris (space dust) or the like.

FIG. 8B shows an illumination-equipped utility pole including a photoelectric conversion module 810 and a photoelectric conversion module fixture mechanism 811. An illumination device 812 is operated using electric power generated by the photoelectric conversion module 810. The electric power which is not used for operating the illumination device 812 is transmitted to a power station or the like via a transmission wire 813. The photoelectric conversion module 810 has the mechanism described in this specification and generates a large amount of electric power because the incident light can be converted into electricity efficiently. Accordingly, since a large amount of electric power can be obtained stably, an illumination device having a large amount of light can be provided for improving the safety during the night. Note that in the case where the photoelectric conversion module according to the present invention is used under an enviromnent where the maintenance is relatively easy like the illumination-equipped utility pole, the structure in which the reflection member is provided over the sealing layer as shown in Embodiment 2 is preferable. This makes it possible to replace the reflection member which has deteriorated and to suppress a decrease in amount of electric power to be generated by the photoelectric conversion module.

This application is based on Japanese Patent Application serial no. 2010-254155 filed with Japan Patent Office on Nov. 12, 2010, the entire contents of which are hereby incorporated by reference.

What is claimed is:

1. A photoelectric conversion module comprising:
a protective layer;
photoelectric conversion cells provided over the protective layer; and
a reflection member provided for at least one of a space between the photoelectric conversion cells and a periphery of the photoelectric conversion cells, wherein the reflection member has a substantially triangular cross-sectional shape,
wherein the reflection member has a peak portion higher than a surface of the photoelectric conversion cells, and
wherein a surface of the reflection member reflects 70% or more of visible light and infrared light.

2. The photoelectric conversion module according to claim 1,
wherein an intersecting angle between the protective layer and a straight line connecting the peak portion of the reflection member and an end portion of a bottom of the reflection member is more than 45° and less than 90°.

3. The photoelectric conversion module according to claim 1,
wherein an area where the reflection member overlaps with the photoelectric conversion cells is smaller than an area where the reflection member overlaps with the space between the photoelectric conversion cells or the periphery of the photoelectric conversion cells.

4. The photoelectric conversion module according to claim 1,
wherein the reflection member is detachable.

5. A photoelectric conversion device comprising the photoelectric conversion module according to claim 1, wherein the photoelectric conversion device has a function of automatically controlling an angle of the photoelectric conversion module by sequentially tracking a position of a light source.

6. A photoelectric conversion module comprising:
a protective layer;
photoelectric conversion cells provided over the protective layer;
a sealing layer for covering the photoelectric conversion cells; and
a reflection member provided over the sealing layer,
wherein the reflection member has a substantially triangular cross-sectional shape,
wherein the reflection member has a peak portion higher than a surface of the photoelectric conversion cells,
wherein a surface of the reflection member reflects 70% or more of visible light and infrared light, and
wherein the reflection member overlaps at least one of with a space between the photoelectric conversion cells and with a periphery of the photoelectric conversion cells.

7. The photoelectric conversion module according to claim 6,
wherein an intersecting angle between the protective layer and a straight line connecting the peak portion of the reflection member and an end portion of a bottom of the reflection member is more than 45° and less than 90°.

8. The photoelectric conversion module according to claim 6,
wherein an area where the reflection member overlaps with the photoelectric conversion cells is smaller than an area where the reflection member overlaps with the space between the photoelectric conversion cells or the periphery of the photoelectric conversion cells.

9. The photoelectric conversion module according to claim 6,
wherein the reflection member is detachable.

10. A photoelectric conversion device comprising the photoelectric conversion module according to claim 6, wherein the photoelectric conversion device has a function of automatically controlling an angle of the photoelectric conversion module by sequentially tracking a position of a light source.

11. A photoelectric conversion module comprising:
a protective layer;
photoelectric conversion cells provided over the protective layer;
a sealing layer over the photoelectric conversion cells; and
a reflection member over the sealing layer,
wherein the reflection member has a substantially triangular cross-sectional shape,
wherein the reflection member has a peak portion higher than the photoelectric conversion cells,
wherein a surface of the reflection member reflects 70% or more of visible light and infrared light, and
wherein the reflection member overlaps at least one of with a space between the photoelectric conversion cells and with a periphery of the photoelectric conversion cells.

12. The photoelectric conversion module according to claim 11,
wherein an intersecting angle between the protective layer and a straight line connecting the peak portion of the reflection member and an end portion of a bottom of the reflection member is more than 45° and less than 90°.

13. The photoelectric conversion module according to claim 11,
wherein an area where the reflection member overlaps with the photoelectric conversion cells is smaller than an area where the reflection member overlaps with the space between the photoelectric conversion cells or the periphery of the photoelectric conversion cells.

14. The photoelectric conversion module according to claim 11,
wherein the reflection member is detachable.

15. A photoelectric conversion device comprising the photoelectric conversion module according to claim 11, wherein the photoelectric conversion device has a function of automatically controlling an angle of the photoelectric conversion module by sequentially tracking a position of a light source.
